(19) United States
(12) Patent Application Publication
(10) Pub. No.: US 2005/0224110 A1
(43) Pub. Date: Oct. 13, 2005

(54) Terminal box for a solar battery module and a method of mounting it

(75) Inventors: Hiroyuki Yoshikawa, Yokkaichi-City (JP); Makoto Higashikozono, Yokkaichi-City (JP)

Correspondence Address: CASELLA & HESPOS, 274 MADISON AVENUE, NEW YORK, NY, 10016, US

(73) Assignee: Sumitomo Wiring Systems, Ltd., Yokkaichi-City (JP)

(21) Appl. No.: 11/104,116

(22) Filed: Apr. 12, 2005

(30) Foreign Application Priority Data
Apr. 13, 2004 (JP) 2004-117828

(51) Int. Cl. H01L 31/00

(52) U.S. Cl. 136/251; 136/200; 136/293; 136/244

(57) ABSTRACT

A terminal box for a solar battery module is provided and has good heat discharging characteristics and good connection reliability. A bypass diode (50) has a mesa bear chip diode (51) and a pair of conductor plates (52) connected with the bear chip diode (51) while holding the bear chip diode (51) therebetween. The respective conductor plates (52) are superimposed on terminal plates (30) juxtaposed on a base plate (11) along their plane direction, and ultrasonic vibration is applied to each superimposed portion (60) to join it with the corresponding terminal plate (30). The conductor plates (52) include an N-conductor plate (52A) that is thicker than a P-conductor plate (52B).

### BACKGROUND OF THE INVENTION

1. Field of the Invention

The invention relates to a terminal box for a solar battery module and to a method of mounting it.

2. Description of the Related Art

A solar energy generation system is constructed to supply direct-current electricity from a solar battery panel laid on the roof of a house to electric equipment via an inverter or the like. The solar battery panel has a plurality of solar battery modules, and electrodes of the respective solar battery modules are connected in series or in parallel via terminal boxes.

Japanese Patent Publication No. 3498945 discloses a known terminal box with a plurality of terminal plates juxtaposed in a box. Ends of the terminal plates at one side are connectable with positive and negative electrodes drawn out from the underside of the solar battery module and the other ends thereof are connectable with cables for external connection. Bear chip diodes span between adjacent terminal plates for shorting an inverse current at the time of an inverse load from one cable for external connection to the other. The bear chip diode has a diode functioning portion and a pair of conductor pieces connected with the diode functioning portion by soldering while holding the diode functioning portion therebetween. The respective conductor pieces also are connected with the corresponding terminal plates by soldering. The bear chip diode has an advantage of being inexpensive and small as compared to a diode of the package type.

Heat of molten solder is transferred to the diode functioning portion via the conductor pieces while the conductor pieces are solder-welded to the corresponding terminal plates. As a result solder applied between the diode functioning portion and the conductor pieces is melted again, leading to poor connection between the diode functioning portion and the conductor pieces.

As a countermeasure, the conductor piece could be connected with the corresponding terminal plate by resistance welding. However, by resistance welding, it is necessary to provide the terminal plate with unevenness and concentrate a current on spots. Thus, a contact area of the conductor piece and the terminal plate becomes smaller, and heat generated by the diode functioning portion cannot be discharged effectively to the terminal plate.

The present invention was developed in view of the above problem and an object thereof is to provide a terminal box for a solar battery module having good heat discharging characteristics and good connection reliability.

### SUMMARY OF THE INVENTION

The invention relates to a terminal box for a solar battery module. The terminal box includes a box main body. Terminal plates are juxtaposed in the box main body and are connectable with positive and negative electrodes of a solar battery module via cables. A rectifying device spans between two corresponding terminal plates and includes a rectifying-device main body and two conductor plates connected with the rectifying-device main body. The two conductor plates are at least partly superimposed on the corresponding terminal plates along the plane direction thereof. Ultrasonic vibration is applied to superimposed portions to join the conductor plates with the corresponding terminal plates. Thus, the welding operation can be carried out in a shorter time and with a smaller temperature increase as compared to solder-welding. As a result, connection reliability is ensured without adversely affecting the connections between the rectifying-device main body and the conductor plates. Further, ultrasonic welding achieves a larger joined area of the conductor plate and the terminal plate than typically could be achieved by resistance welding. Thus, heat discharging characteristics are good for letting the heat generated by the rectifying-device main body to escape toward the terminal plate.

The rectifying device preferably is provided for bypassing at the time of an inverse load.

The rectifying device main body preferably is chip-shaped and/or the pair of conductor plates are connected with the rectifying-device main body while holding the rectifying-device main body therebetween.

Preferably, the rectifying-device main body is a mesa bear chip diode. An N-conductor plate connectable with an N-area of the bear chip diode is thicker than a P-conductor plate connectable with a P-area of the bear chip diode. Thus, the heat generated by the rectifying-device main body can escape effectively via the N-conductor plate, and the heat discharging characteristics are better. A contact area of the N-area with the N-conductor plate is larger than that of the P-area with the P-conductor plate in the mesa bear chip diode. Thus, heat is discharged actively from the N-conductor plate.

At least one of the conductor plates (preferably the P-conductor plate) may be provided with a stress relieving portion for absorbing a stress created upon applying the ultrasonic vibration. The stress relieving portion includes at least one narrow strip formed by making a bore or recess in the conductor plate at an intermediate position substantially along the extending direction of the conductor plate and a lateral edge of the base end of the narrow strip preferably is arcuate. Thus, the base end of the narrow strip piece is not like to be fractured by the ultrasonic vibration.

Two or more narrow strips preferably are provided. Thus, the heat discharge characteristics can be better as compared to a case where only one narrow strip is provided.

One or more holes for permitting an access to the terminal plates preferably are formed in the base plate at positions substantially corresponding to the superimposed portions. Thus, ultrasonic welding can be applied with the terminal plate and the conductor plate held between an anvil and a horn chip, for example, by inserting the leading end of the anvil into the hole to bring it into contact with the terminal plate.

The invention also relates to a method of mounting or assembling a terminal box for a solar battery module. The method includes providing a box main body. The method then includes arranging a plurality of terminal plates juxtaposed in the box main body for connection with positive and negative electrodes of a solar battery module via respective cables. The method continues by providing a rectifying device spanning between two corresponding terminal plates and including a rectifying-device main body and a pair of conductor plates connected with the rectifying-device main body. The method proceeds by superimposing the pair of conductor plates on the corresponding terminal plates along the plane direction thereof, and applying ultrasonic vibration to superimposed portions to join the conductor plates with the corresponding terminal plates.

The method may further include forming one or more holes in the base plate at positions substantially corresponding to the superimposed portions for permitting an access to the terminal plates.

The method preferably includes forming at least one of the conductor plates with a stress relieving portion for absorbing a stress created upon applying the ultrasonic vibration. The stress relieving portion includes at least one narrow strip piece formed by making a bore or recess in the conductor plate at an intermediate position along an extending direction of the conductor plate and a lateral edge of the base end of the narrow strip piece preferably is arcuately formed.

These and other objects, features and advantages of the present invention will become more apparent upon reading of the following detailed description of preferred embodiments and accompanying drawings. It should be understood that even though embodiments are separately described, single features thereof may be combined to additional embodiments.

### BRIEF DESCRIPTION OF THE DRAWINGS

FIG. 1 is a plan view of a box main body according to one embodiment of the invention.

FIG. 2 is an enlarged plan view of a bypass diode.

FIG. 3 is a diagrammatic section of the structure of a bear chip diode.

FIG. 4 is a diagrammatic section showing a state where ultrasonic welding is applied with a terminal plate and a conductor plate held between an anvil and a horn chip.

### DETAILED DESCRIPTION OF THE PREFERRED EMBODIMENTS

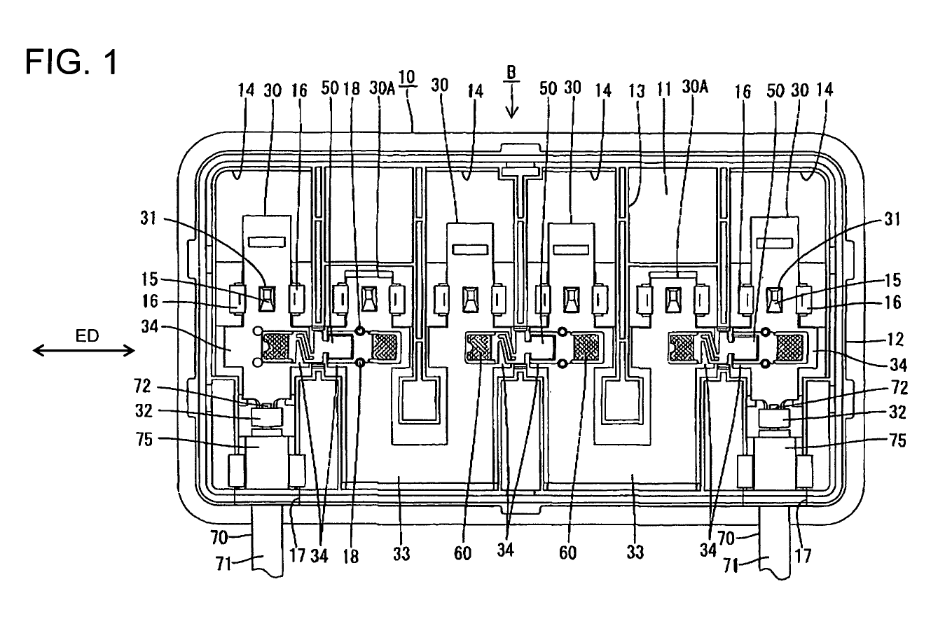

One preferred embodiment of the present invention is described with reference to FIGS. 1 to 4. A terminal box B for a solar battery module according to this embodiment is mounted on the underside of a solar battery module (not shown) having a multitude of solar battery cells connected in series and arranged on the outer surface thereof. The terminal box B has a box main body 10, a multitude of terminal plates 30 juxtaposed in the box main body 10, and bypass diodes for reverse current flow (i.e. a rectifying device) span between adjacent terminal plates 30.

The box main body 10 is made e.g. of a synthetic resin material substantially into a box shape having an open upper surface, and an insulating resin is filled into the inside of the box main body 10 while a cover (not shown) is mounted from the open side or above. The box main body 10 has substantially rectangular base plate 11 on which the terminal plates 30 are arranged substantially side by side. A side plate 12 stands up from the outer peripheral edge of the base plate 11 to surround the base plate 11. Partition walls 13 stand up at specified positions of the base plate 11 to partition the adjacent terminal plates 30. The base plate 11 has four substantially rectangular openings 14, and the leading ends of the corresponding terminal plates 30 face the respective openings 14. Leads (not shown) connected with positive and negative electrodes of the solar battery module are introduced into the respective openings 14 of the base plate 11 and are connectable with the leading ends of the terminal plates 30 by soldering.

Positioning projections 15 are engageable with positioning holes 31 of the terminal plates 30 and project from the upper surface of the base plate 11 substantially in correspondence with the respective terminal plates 30. Two resiliently deformable locking pieces 16 project at the opposite outer sides of each positioning projection 15. In the process of mounting the terminal plate 30, the respective locking pieces 16 are deformed out to widen the spacing therebetween by engaging the opposite lateral edges of the terminal plate 30. As the terminal plate 30 is mounted properly, the locking pieces 16 are restored to press the opposite lateral edges of the terminal plate 30 from above, thereby preventing the terminal plate 30 from moving upward.

Notches 17 are formed at the opposite ends of the upper edge of the side plate 12. Cables 70 for external output are fit into the notches 17 from above and cable pressing portions 75 are fit therein to fix the cables 70. The fitted cable pressing portions 75 are unitarily continuous with the side plate 12. The partition walls 13 extend substantially along the outer shapes of the terminal plates 30 and guide the terminal plates 30 for mounting.

The terminal plates 30 are formed by cutting or pressing an electrically metal conductive plate into strips. The terminal plates 30 are arranged at the opposite ends of the base plate 11 and are connected with the corresponding cables 70 for external output. An insulation coating 71 is stripped at an end of each cable 70 to expose a core 72, and a barrel 32 at an end of the terminal plate 30 is crimped, bent or folded into connection with the cable 70 and the terminal plate 30.

Couplings 33 unitarily join adjacent pairs of terminal plates 30, 30A excluding those connected with the cables 70. One terminal plate 30A in each pair does not contact the lead of the solar battery module. This terminal plate 30A is shorter than the other terminal plate 30 and has the leading end surrounded by the partition walls 13. Thus, this terminal plate 30A is arranged to detour from the other terminal plate 30 without being directly involved in connection with the mating side, and a creepage distance for the escape of heat generated by a bear chip diode 51 is lengthened by this detour, thereby improving a heat discharging effect.

Attachments 34 are provided at opposite lateral edges of each terminal plate 30 and bulge out sideways. Edges of the attachments 34 at the projecting ends are opposed to each other between the adjacent terminal plates 30. Bypass diodes 50 span between the adjacent terminal plates 30. In the illustrated embodiment, three bypass diodes 50 are arranged substantially on the same straight line while crossing the respective terminal plates 30.

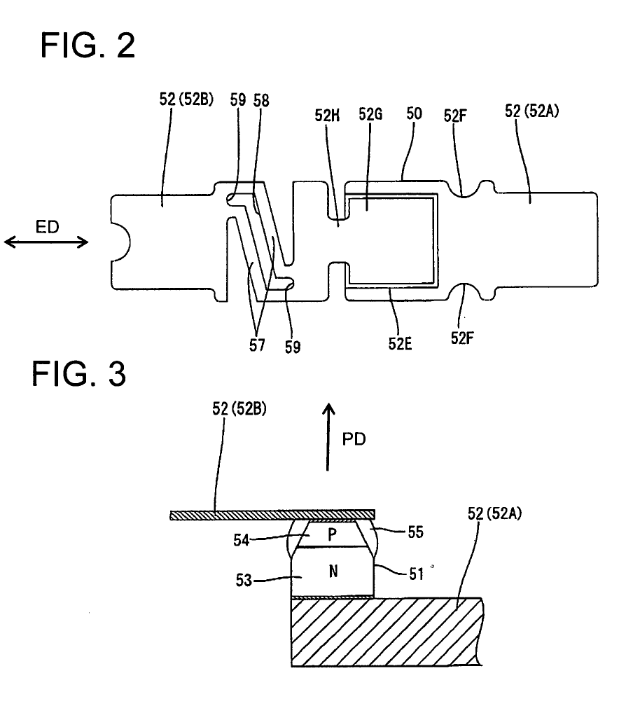

As shown in FIGS. 2 to 4, each bypass diode 50 has a mesa bear or surface etched chip diode 51, and two conductor plates 52 electrically connected with the bear chip diode 51 while holding the bear chip diode 51 from opposite sides along the thickness direction of the bypass diode 50. As shown in FIG. 3, the bear chip diode 51 has a multilayer structure with a P-area 54 placed on an N-area 53. The areas 54, 53 form a substantially trapezoidal or tronco-conic shape. A glass film 55 is provided at least partly around this multilayer structure. The conductor plates 52 include an N-conductor plate 52A contacting the N-area 53 and a P-conductor plate 52B contacting the P-area 54. The N-conductor plate 52A is thicker than the P-conductor plate 52B (preferably more than about twice as thick, most preferably more than about 6 times as thick). For example, the P-conductor plate 52B is about 0.1 mm thick, whereas the N-conductor plate 52A is about 0.8 to 1.0 mm thick.

The N-conductor plate 52A is superimposed on the attachment portion 34 of the terminal plate 30 in thickness direction to extend substantially along the plane direction PD of the attachment portion 34. More specifically, the N-conductor plate 54A includes a contact portion 52E to be connected with the N-area 53 of the bear chip diode 51 by soldering, welding or the like, and extends from the contact portion 52E at an angle, preferably substantially normal to the extending direction of the corresponding terminal plate 30. Substantially arcuate recesses 52F are formed at opposite lateral edges of the N-conductor plate 52A at an intermediate position substantially along the extending direction of the N-conductor plate 52A. Projecting pins 18 project from the base plate 11 and engage the respective recesses 52F (see FIG. 1) to prevent the conductor plate 52 from moving loosely along the width direction at the time of being welded to the terminal plate 30.

The P-conductor plate 52B has a substantially rectangular contact portion 52G to be connected with the P-area 54 of the bear chip diode 51 by soldering, welding or the like, and extends from the contact portion 52G in a direction substantially opposite from the N-conductor plate 52A via a constricted portion 52H. A bore or recess of a specified shape is formed in an intermediate section of the P-conductor plate 52B along the extending direction ED of the P-conductor plate 52B. As this bore is made, two narrow strips 57 are formed to extend oblique to the extending direction ED. The P-conductor plate 52B is deformable to extend and contract along the extending direction ED thereof by the presence of the narrow strips 57, thereby absorbing stress and compensating changes in distance of the respective parts created at the time of welding to the terminal plate 30. The two narrow strip pieces 57 are substantially identically shaped and sized, have substantially the same width over the entire length, and are substantially parallel with each other with a slit 58 located therebetween. Lateral edges at the base ends of the narrow strips 57 facing the slit 58 are arcuate so that the lateral edges of the respective narrow strip pieces 57 are continuous with each other via substantially rounded portions 59. Thus, the slit 58 has rounded distal ends.

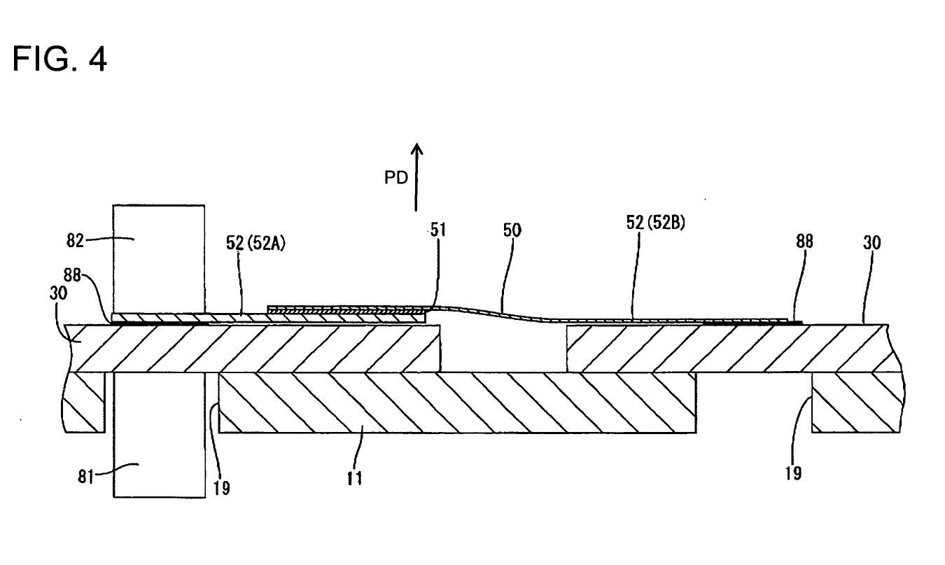

An extending end of the P-conductor plate 52B is at least partly superimposed on the corresponding terminal plate 30 along its plane direction PD, and ultrasonic welding applied to this superimposed portion 60 (hatched portion shown in FIG. 1) to connect the superimposed portion 60 to the corresponding terminal plate 30. Likewise, the N-conductor plate 52A is at least partly superimposed on the corresponding terminal plate 30 along its plane direction PD, and ultrasonic welding is applied to a superimposed portion 60 at the extending end of the N-conductor plate 52A away from the contact portion 52E to connect the superimposed portion 60 to the corresponding terminal plate 30. The terminal plate 30 and the conductor plate 52 are held between an anvil 81 and a horn chip 82 for the ultrasonic welding. In order to enable this, the base plate 11 of the box main body 10 has holes 19 at positions corresponding to the respective superimposed portions 60 so that the leading end of the anvil 81 can get close to the terminal plate 30 (see FIG. 4).

The barrels 32 of the terminal plates 30 are crimped into connection with the cores 72 exposed at the ends of the corresponding cables 70 to connect the terminal plates 30 and the cables 70. The terminal plates 30 then are fixed on the base plate 11. At this time, the positioning projections 15 on the base plate 11 are inserted into the positioning holes 31 of the terminal plates 30 to position the terminal plates 30. Additionally, the locking pieces 16 engage the terminal plates 30 to prevent upward movement.

The cable pressing portions 75 are mounted to cover the cables 70 and to prevent the cables 70 from making loose movements. The bypass diodes 50 are placed to span between the adjacent terminal plates 30. At this time, the bypass diodes 50 are positioned by engaging the recesses 52F of the N-conductor plates 52A with the projecting pins 18 of the base plate 11 for guiding. It should be noted that each bypass diode used here is an integral assembly of the bear chip diode 51 and the conductor plates 52.

The superimposed portion 60 of the conductor plate 52 and the terminal plate 30 is held between the anvil 81 and the horn chip 82 of an ultrasonic welding apparatus, and ultrasonic energy is applied thereto. More specifically, as shown in FIG. 4, the base plate 11 is placed on the anvil 81 so that the leading end of the anvil 81 is inserted into the hole of the base plate 11. The horn chip 82 then is moved to press the conductor plate 52 against the terminal plate 30. Ultrasonic vibration with a vibrating direction along the plane direction PD of the conductor plate 52 is applied to the horn chip 82 to ultrasonically weld the conductor plate 52 to the terminal plate 30. Thus, the conductor plate 52 and the terminal plate 30 are connected with an ultrasonically welded portion 88.

The box main body 10 is mounted to the underside of the solar battery module, preferably with an adhesive double-coated tape or bolts. In the mounting process, the leads connected with the electrodes of the solar battery module are drawn into the box main body 10 through the openings 14 of the base plate 11 and are soldered with the leading ends of the terminal plates 30. An insulating resin, such as a silicone, then is filled into the box main body 10, and the cover is mounted to close the box main body 10. The crimp-connected parts, the solder-connected parts, the (ultrasonically) welded portions 88 and/or the like connected parts are sealed airtight by the insulating resin.

As described above, conductor plates 52 are at least partly superimposed on the corresponding terminal plates 30 along the plane direction PD, and heat is applied, preferably by ultrasonic welding, to join the superimposed portions 60 of the conductor plates 52 and the terminal plates 30. Ultrasonic welding can be carried out in less time than solder welding, thereby suppressing a temperature increase. This avoids remelting the solder applied between the bear chip diode 51 and the conductor plates 52, thereby ensuring connection reliability. Further, the bear chip diode 51 and the conductor plates 52 can be connected by lead-free solder having a low melting point. Thus, an environmental benefit is obtained. Furthermore, a joined area of the conductor plate 52 and the terminal plate 30 is larger by ultrasonic welding than by resistance welding. Thus, heat generated by the bear chip diode 51 can escape toward the terminal plate 30 more effectively.

The N-conductor plate 52A is thicker than the P-conductor plate 52B. Thus, the heat generated by the bear chip diode 51 can escape effectively via the N-conductor plate 52A, and the heat discharging characteristics are better. Heat discharging characteristics are even better in this embodiment since the N-conductor plate 52A and the terminal plate 30 are placed one over the other below the bear chip diode 51.

Further, the P-conductor plate 52B is thinned and bored at the intermediate position along the extending direction ED to form the narrow strips 57. Thus, stresses created by the ultrasonic vibration are absorbed and dampened by the narrow strips 57. Additionally, the lateral edges at the base ends of the narrow strips 57 are rounded to prevent fractures in response to the ultrasonic vibration. Furthermore, the narrow strips 57 provide better heat discharging effect as compared to only one narrow strip.

The invention is not limited to the above described and illustrated embodiment. For example, the following embodiments are also embraced by the technical scope of the present invention as defined by the claims. Beside the following embodiments, various changes can be made without departing from the scope and spirit of the present invention as defined by the claims.

Although the box main body is entirely resin-sealed in the foregoing embodiment, it is sufficient to resin-seal at least around the connected parts such as the ultrasonically welded portions according to the present invention.

Although two narrow strips 57 are provided in the foregoing embodiment, three or more narrow strips may be provided according to the invention. Depending on cases, only one narrow strip may be provided.

Although the anvil can enter the holes of the base plate in the foregoing embodiment, a welding instrument used for welding other than ultrasonic welding may enter the holes of the base plate according to the present invention.

1. A terminal box (B) for a solar battery module, comprising:
a box main body (10),
a plurality of terminal plates (30) juxtaposed in the box main body (10) and connectable with positive and negative electrodes of a solar battery module via respective cables (70), and
a rectifying device (50) spanning between two corresponding terminal plates (30) and including a rectifying-device main body (51) and two conductor plates (52A, 52B) connected with the rectifying-device main body (51),
wherein the two conductor plates (52A, 52B) are at least partly superimposed on the corresponding terminal plates (30) along a plane direction (PD) thereof, and the superimposed portions are welded ultrasonically.

2. The terminal box of claim 1, wherein the rectifying device (50) is provided for bypassing at the time of an inverse load.

3. The terminal box of claim 1, wherein the rectifying device main body (51) is chip-shaped and the two conductor plates (52A, 52B) are connected with the rectifying-device main body (51) while holding the rectifying-device main body (51) therebetween.

4. The terminal box of claim 1, wherein the rectifying-device main body (51) is a mesa bear chip diode, and the two conductor plates (52A, 52B) include an N-conductor plate (52A) a P-conductor plate (52B), the N-conductor plate (52A) being connectable with an N-area of the bear chip diode (51) and being thicker than a P-conductor plate (52B) connectable with a P-area of the bear chip diode (51).

5. The terminal box of claim 1, wherein at least one (52B) of the conductor plates (52A, 52B) is provided with a stress relieving portion (57) for absorbing a stress created upon applying the ultrasonic vibration, the stress relieving portion includes at least one narrow strip (57) formed by making a bore or recess in the conductor plate (52B) at an intermediate position along an extending direction (ED) of the conductor plate (52B) and a lateral edge of the base end of the narrow strip (57) being arcuately formed.

6. A terminal box according to claim 5, wherein a plurality of narrow strips (57) are provided.

7. A terminal box (B) for a solar battery module, comprising:
a plurality of terminal plates (30) connectable with positive and negative electrodes of a solar battery module via respective cables (70),
a base plate (11) on which the terminal plates (30) are substantially juxtaposed, and
a rectifying device (50) for bypassing at the time of an inverse load, the rectifying device (50) spanning between two corresponding terminal plates (30) and including a rectifying-device main body (51) and two conductor plates (52A, 52B) connected with the rectifying-device main body (51) while holding the rectifying-device main body (51) therebetween,
wherein the two conductor plates (52A, 52B) are at least partly superimposed on the corresponding terminal plates (30) along the plane direction (PD) thereof, the superimposed portions are welded to be joined with the corresponding terminal plates (30), and at least one hole (19) formed in the base plate (11) at positions substantially corresponding to the superimposed portions for permitting an access to the terminal plates (30).

8. A method of mounting a terminal box (B) for a solar battery module, comprising:
providing a box main body (10),
arranging a plurality of terminal plates (30) juxtaposed in the box main body (10) to be connectable with positive and negative electrodes of a solar battery module via respective cables (70), and
spanning a rectifying device (50) between two corresponding terminal plates (30), the rectifying device (50) including a rectifying-device main body (51) and a pair of conductor plates (52A, 52B) connected with the rectifying-device main body (51),
at least partly superimposing the pair of conductor plates (52A, 52B) on the corresponding terminal plates (30) along a plane direction (PD) thereof, and
applying ultrasonic vibration to superimposed portions to join the conductor plates (52A, 52B) with the corresponding terminal plates (30).

9. The method of claim 8, wherein at least one (52B) of the conductor plates (52A, 52B) is provided with a stress relieving portion (57) for absorbing a stress created upon applying the ultrasonic vibration, the stress relieving portion includes at least one narrow strip (57) formed by making a bore or recess in the conductor plate (52B) at an intermediate position along an extending direction (ED) of the conductor plate (52B) and a lateral edge of the base end of the narrow strip (57) is arcuate.

10. A method of mounting a terminal box (B) for a solar battery module, comprising the following steps:
arranging a plurality of terminal plates (30) connectable with positive and negative electrodes of a solar battery module via respective cables (70) on a base plate (11), and
spanning a rectifying device (50) between two corresponding terminal plates (30), the rectifying device (50) including a rectifying-device main body (51) and a pair of conductor plates (52A, 52B) connected with the rectifying-device main body (51),
at least partly superimposing the pair of conductor plates (52A, 52B) on the corresponding terminal plates (30) along a plane direction (PD) thereof,
welding the superimposed portions to be joined with the corresponding terminal plates (30), and
forming at least one holes (19) in the base plate (11) at positions substantially corresponding to the superimposed portions for permitting an access to the terminal plates (30).
